(19) United States
(12) Patent Application Publication
(10) Pub. No.: US 2019/0079549 A1
(43) Pub. Date: Mar. 14, 2019

(54) SUPPLY CIRCUITS, DEVICES AND METHODS RELATED TO RADIO-FREQUENCY AMPLIFIERS

(71) Applicant: SKYWORKS SOLUTIONS, INC., Woburn, MA (US)

(72) Inventors: Lui LAM, Lexington, MA (US); Mark M. DOHERTY, Westford, MA (US)

(21) Appl. No.: 16/128,408

(22) Filed: Sep. 11, 2018

Related U.S. Application Data
(60) Provisional application No. 62/557,651, filed on Sep. 12, 2017.

(51) Int. Cl. G05F 1/56; H03F 3/213; H03F 3/24; H04B 1/48

(52) U.S. Cl. CPC G05F 1/56; H04B 1/48; H03F 3/245; H03F 3/213

(57) ABSTRACT

Supply circuits, devices and methods related to radio-frequency amplifiers. In some embodiments, an amplification system can include an amplifier circuit having a plurality of stages and configured to amplify a signal. The amplification system can further include a supply circuit configured to provide a regulated supply voltage to at least one stage of the plurality of stages, and an unregulated supply voltage to at least one stage of the plurality of stages. In some embodiments, the amplifier circuit can be implemented as a power amplifier circuit.

### CROSS-REFERENCE TO RELATED APPLICATION(S)

This application claims priority to U.S. Provisional Application No. 62/557,651 filed Sep. 12, 2017, entitled SUPPLY CIRCUITS, DEVICES AND METHODS FOR RADIO-FREQUENCY AMPLIFIERS, the disclosure of which is hereby expressly incorporated by reference herein in its respective entirety.

### BACKGROUND

### Field

The present disclosure relates to supply circuits, devices and methods related to radio-frequency amplifiers.

### Description of the Related Art

In wireless applications, radio-frequency (RF) amplifiers are utilized to amplify signals. For example, a signal to be transmitted can be amplified by a power amplifier. Such an amplified signal can then be routed to an antenna through, for example, a filter and an antenna switch.

### SUMMARY

In accordance with a number of implementations, the present disclosure relates to amplification system that includes an amplifier circuit having a plurality of stages and configured to amplify a signal. The amplification system further includes a supply circuit configured to provide a regulated supply voltage to at least one stage of the plurality of stages, and an unregulated supply voltage to at least one stage of the plurality of stages.

In some embodiments, the supply circuit can include a regulator configured to provide the regulated voltage. The regulator can include, for example, a low-dropout regulator.

In some embodiments, the at least one stage being provided with the unregulated voltage can include a final one of the plurality of stages. In some embodiments, the supply circuit can be configured to provide the unregulated voltage to only the final stage, and the regulated voltage to the other stage(s).

In some embodiments, the unregulated voltage can be based on a battery voltage. In some embodiments, the unregulated voltage can be substantially same as the battery voltage.

In some embodiments, the amplifier circuit can be configured as a power amplifier circuit. The signal amplified by the power amplifier circuit can be configured for transmission.

In some embodiments, the amplification system can be configured as at least a part of a front-end system. In some embodiments, the amplification system can be configured to support a wireless operation.

In some teachings, the present disclosure relates to a method for amplifying a signal. The method includes providing a signal to a power amplifier circuit having a plurality of stages. The method further includes supplying a regulated supply voltage to at least one stage of the plurality of stages, and an unregulated supply voltage to at least one stage of the plurality of stages.

In some implementations, the present disclosure relates to a radio-frequency module that includes a packaging substrate configured to support a plurality of components, and an amplification system implemented on the packaging substrate. The amplification system includes an amplifier circuit having a plurality of stages and configured to amplify a signal. The amplification system further includes a supply circuit configured to provide a regulated supply voltage to at least one stage of the plurality of stages, and an unregulated supply voltage to at least one stage of the plurality of stages.

In some embodiments, the amplifier circuit can be implemented on a semiconductor die which is then mounted on the packaging substrate. In some embodiments, the supply circuit can be implemented on the semiconductor die, or on another semiconductor die.

In some embodiments, the amplifier circuit can be configured as a power amplifier circuit. In some embodiments, the radio-frequency module can be configured as a front-end module. In some embodiments, such a front-end module can further include an antenna switch circuit configured to route the amplified signal from the power amplifier circuit to an antenna for transmission.

In a number of implementations, the present disclosure relates to a wireless device that includes a transceiver configured to process a signal, and a front-end module in communication with the transceiver. The front-end module includes an amplifier circuit having a plurality of stages and configured to amplify the signal. The front-end module further includes a supply circuit configured to provide a regulated supply voltage to at least one stage of the plurality of stages, and an unregulated supply voltage to at least one stage of the plurality of stages. The wireless device further includes an antenna in communication with the front-end module and configured to support an operation associated with the signal.

In some embodiments, the amplifier circuit can be configured as a power amplifier circuit, and the signal can be configured to be transmitted through the antenna.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows depicts an amplification system having one or more features as described herein.

FIG. 2 shows a front-end system that can include one or more features of the amplification system of FIG. 1.

FIG. 3 shows an example amplification system in which each stage of an amplifier circuit is provided with a supply voltage Vbat.

FIG. 4 shows an example amplification system in which a regulated voltage is supplied to each stage of an amplifier circuit.

FIG. 5A shows that in some embodiments, an amplification system can include a supply circuit configured to provide a regulated supply voltage to some of a plurality of stages of an amplification circuit, and to provide an unregulated supply voltage to the other stage(s) of the amplification circuit.

FIG. 5B shows that in some embodiments, use of a combination of regulated/unregulated voltages can be selectively controlled.

FIG. 6 shows an example configuration that can be a variation to the example amplification system of FIG. 5A.

FIG. 7 shows another example configuration that can be a variation to the example amplification system of FIG. 5A.

FIG. 8 shows that in some embodiments, an amplification system having one or more features as described herein can be implemented in a module.

FIG. 9 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

Many electronic devices such as wireless devices are powered by batteries. In a wireless device, a radio-frequency (RF) front-end can include an amplifier such as a power amplifier for amplifying a signal to be transmitted. Thus, when such an RF front-end amplifier is operated with a supply from a battery with a voltage Vbat (or approximately Vbat or tracking Vbat), relatively large variation in Vbat can impose design challenges for maintaining RF performance over a wide voltage range. For example, it can be challenging to maintain linearity performance over a wide voltage range. In another example, ruggedness of various circuits can be a concern when Vbat is at a maximum or relatively high value.

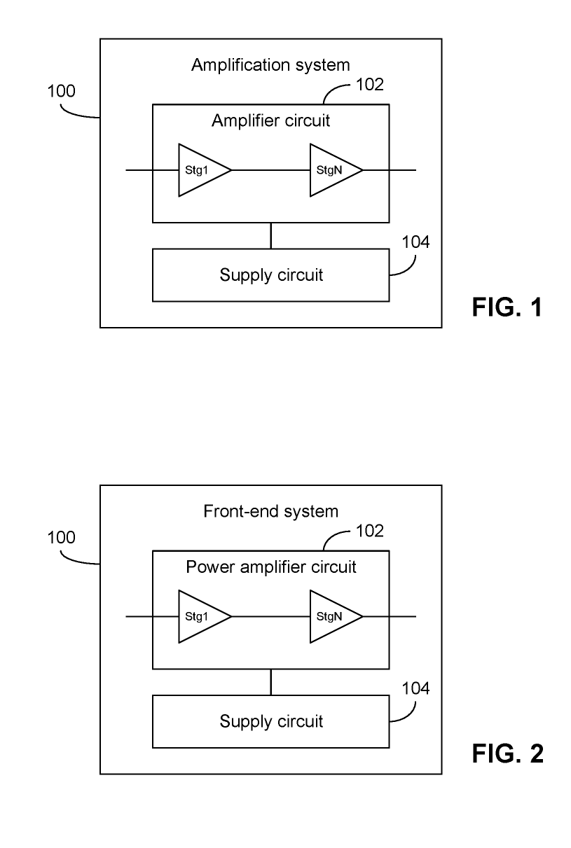

FIG. 1 depicts an amplification system 100 having one or more features as described herein. Such an amplification system can include an amplifier circuit 102 having a plurality of stages, Stage 1 to Stage N, where N can be a positive integer having a value greater than 1. For example, a two-stage amplifier can include stages Stg1 and Stg2. In another example, a three-stage amplifier can include stages Stg1, Stg2 and Stg3.

In FIG. 1, the amplification system 100 is shown to include a supply circuit 104 configured to provide supply signals (e.g., supply voltage) to the stages of the amplifier circuit 102. Examples related to such a supply circuit are described herein in greater detail.

FIG. 2 shows front-end system 100 that can include one or more features of the amplification system 100 of FIG. 1. In some embodiments, the front-end system 100 of FIG. 2 can be a more specific example of the amplification system 100 of FIG. 1.

In the front-end system 100 of FIG. 2, the amplifier circuit (102 in FIG. 1) can be a power amplifier circuit 102 configured to amplify a signal for transmission. Although some examples are described herein in the context of power amplifiers, it will be understood that one or more features of the present disclosure can also be implemented in other types of RF amplifiers, including, for example, low-noise amplifiers.

In the example of FIG. 2, the power amplifier circuit 102 can include a plurality of stages, Stage 1 to Stage N (N>1), similar to the example of FIG. 1. Also similar to the example of FIG. 1, the front-end system 100 is shown to include a supply circuit 104 configured to provide supply signals (e.g., supply voltage) to the stages of the power amplifier circuit 102.

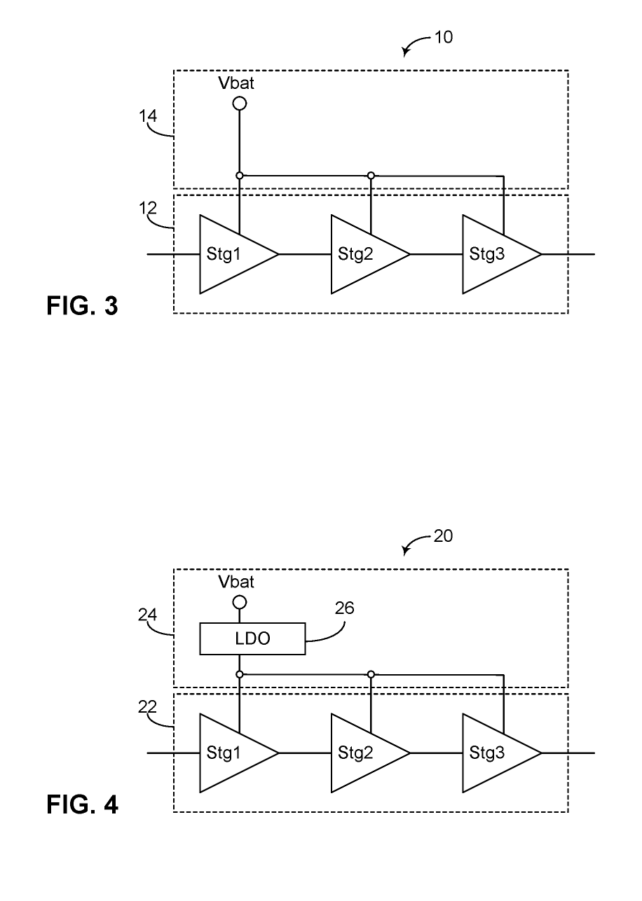

FIG. 3 shows an amplification system 10 in which each of a plurality of stages (e.g., Stg1, Stg2, Stg3) of an amplifier circuit 12 is provided with a supply voltage Vbat. A supply circuit 14 for such an amplification system can include an unregulated battery voltage Vbat being provided to each stage of the amplifier circuit 12. As described above, such an amplification system can result in design and/or performance challenges.

FIG. 4 shows an amplification system 20 in which a regulated voltage is supplied to each stage of an amplifier circuit 22. Accordingly, a supply circuit 24 for such an amplification system can include a regulator 26 such as a low-dropout (LDO) regulator that receives a battery voltage Vbat as an input and provides a regulated output voltage. Such a regulated output voltage is shown to be provided to each of the stages (e.g., Stg1, Stg2, Stg3) of the amplifier circuit 22.

It is noted that in the amplification system 20 of FIG. 4, supplying all of the stages of the amplifier circuit 22 with a regulated voltage can allow good control of performance and ruggedness. However, use of such a regulated supply voltage for all of the stages of the amplifier circuit 22 can result in undesirable features. For example, low or reduced efficiency can result due to power dissipation in the LDO regulator. In another example, challenging requirements can be imposed on LDO regulator bandwidth and output stability, thereby resulting in, for example, increased device size and/or cost.

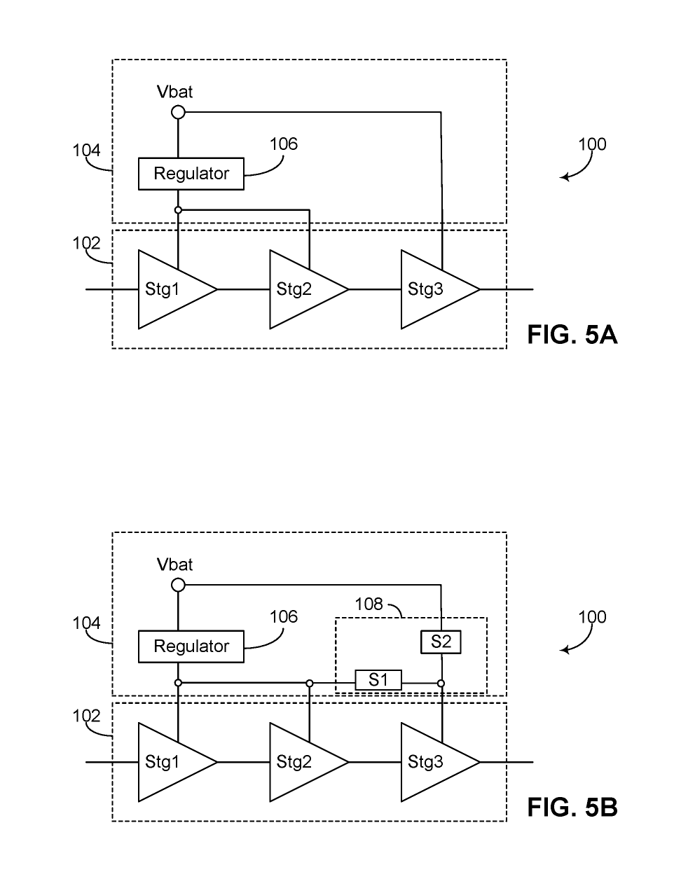

FIG. 5A shows that in some embodiments, an amplification system 100 such as a front-end system can include a supply circuit 104 configured to provide a regulated supply voltage to some of a plurality of stages of an amplification circuit 102, and to provide an unregulated supply voltage to the other stage(s) of the amplification circuit 102. For example, the supply circuit 104 in FIG. 5A is shown to include a regulator 106 (e.g., LDO regulator) that receives a battery voltage Vbat as an input and provides a regulated voltage to each of the first and second stages (Stg1 and Stg2). The third stage (Stg3) is shown to be provided with an unregulated voltage (e.g., directly from the battery voltage Vbat).

For the purpose of description, the amplification circuit 102 is shown to include three stages (Stg1, Stg2, Stg3) similar to the examples of FIGS. 3 and 4; however, it will be understood that other numbers of stages can be implemented utilizing one or more features of the present disclosure. It is also noted that the amplification circuit 102 of FIG. 5A can be a power amplifier circuit; however, one or more features of the regulated/unregulated combination can also be implemented with other types of amplifiers.

In some embodiments, a regulated supply voltage can be provided to all stages of a power amplifier circuit, except the final stage (e.g., Stg3 in FIG. 5A). Such a final stage can be provided with an unregulated supply voltage such as a battery voltage Vbat. With the foregoing configuration, a number of desirable features can be achieved. For example, an improved utilization of supply voltage can be realized for improved output power and efficiency. In another example, significantly reduced loading can be demanded from the regulator; accordingly, minimized or reduced transient glitches and dips in regulated voltage can be achieved. In yet another example, a simpler and more efficient regulator design can be implemented, thereby reducing, for example, overall device size and/or cost associated with the amplification system (100 in FIG. 5A).

It is noted that in some embodiments, performance over voltage (e.g., error vector magnitude (EVM) floor) can be controlled by the regulator (106 in FIG. 5A) and its regulated supply voltage. Any degradation of such performance, if any, due to the unregulated voltage being supplied to the final stage, can be acceptable, especially in view of the foregoing benefits.

FIG. 5B shows that in some embodiments, use of a combination of regulated/unregulated voltages can be selectively controlled. For example, suppose that in some operating condition, use of a regulated supply voltage is desired for all of the stages (e.g., Stg1, Stg2, Stg3) of an amplification circuit 102, while in another operating condition, a combination of regulated/unregulated supply voltages can be utilized (e.g., similar to the example of FIG. 5A). To accommodate such operating configurations, a supply circuit 104 can include a selection circuit 108 that allows a selected stage (e.g., the final stage Stg3) to receive either a regulated supply voltage from the regulator 106, or an unregulated supply voltage (e.g., battery voltage Vbat). For example, to provide the regulated supply voltage to the final stage (Stg3), a first switch 51 can be closed, and a second switch S2 can be opened. To provide the unregulated supply voltage to the final stage (Stg3), the first switch 51 can be opened, and the second switch S2 can be closed. It will be understood that other selection circuit configurations can also be implemented.

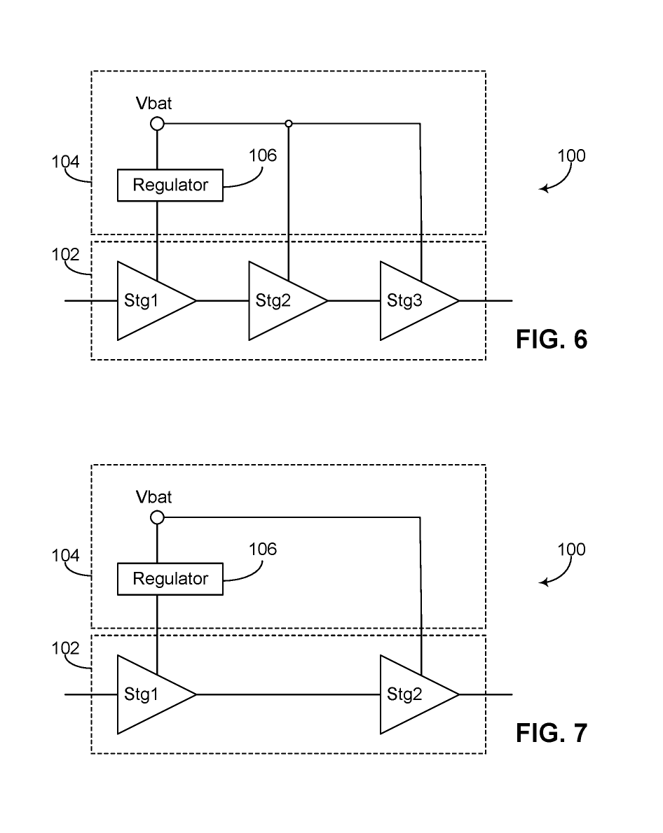

FIGS. 6 and 7 show non-limiting examples of variations to the example of FIG. 5A. It will be understood that similar variations can also be implemented for the example of FIG. 5B.

FIG. 6 shows that in some embodiments, use of unregulated supply voltage is not necessarily limited to the final stage. In the example of FIG. 6, a supply circuit 104 is shown to include a regulator 106 that supplies a regulated voltage to a first stage (Stg1) of an amplifier circuit 102. The supply circuit 104 is further shown to provide an unregulated supply voltage (e.g., Vbat) to second and third stages (Stg2 and Stg3) of the amplifier circuit 102. It will be understood that other combinations of regulated/unregulated supply voltages can also be implemented.

FIG. 7 shows that in some embodiments, one or more features of the present disclosure can be implemented for an amplification system 100 having an amplifier circuit 102 with two stages (Stg1 and Stg2). In the example of FIG. 7, a supply circuit 104 is shown to include a regulator 106 that supplies a regulated voltage to the first stage (Stg1) of the amplifier circuit 102, and an unregulated voltage to the second stage (Stg2) of the amplifier circuit 102. It will be understood that other combinations of regulated/unregulated supply voltages can also be implemented.

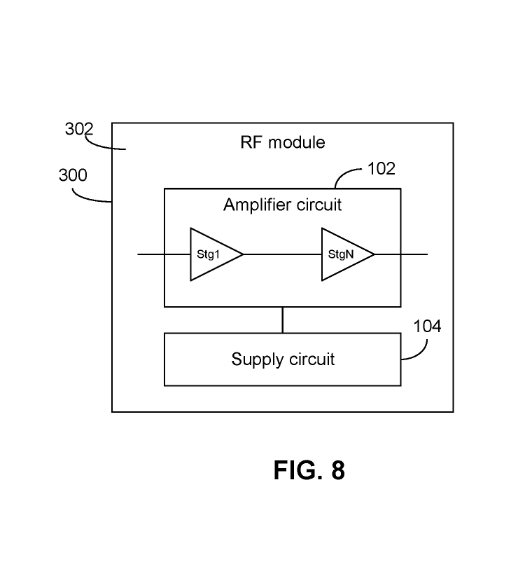

FIG. 8 shows that in some embodiments, an amplification system having one or more features as described herein can be implemented in a module. Such a module can be, for example, an RF module such as a front-end module (FEM). In the example of FIG. 8, a module 300 can include a packaging substrate 302, and a number of components can be mounted on such a packaging substrate. For example, an amplifier circuit 102 having a plurality of stages can be implemented on the packaging substrate 302. In some embodiments, such an amplifier circuit can be implemented on a semiconductor die which is then mounted on the packaging substrate 302.

FIG. 8 further shows that a supply circuit 104 having one or more features as described herein can be implemented on the packaging substrate 302. In some embodiments, at least some of the supply circuit 104 can be implemented on the same semiconductor die as the amplifier circuit 102, on a separate die, off of any die, or any combination thereof.

In some implementations, a power amplification system having one or more features as described herein can be included in an RF device such as a wireless device. Such a power amplification system can be implemented in the wireless device as one or more circuits, as one or more die, as one or more packaged modules, or in any combination thereof. In some embodiments, such a wireless device can include, for example, a cellular phone, a smart-phone, a hand-held wireless device with or without phone functionality, a wireless tablet, etc.

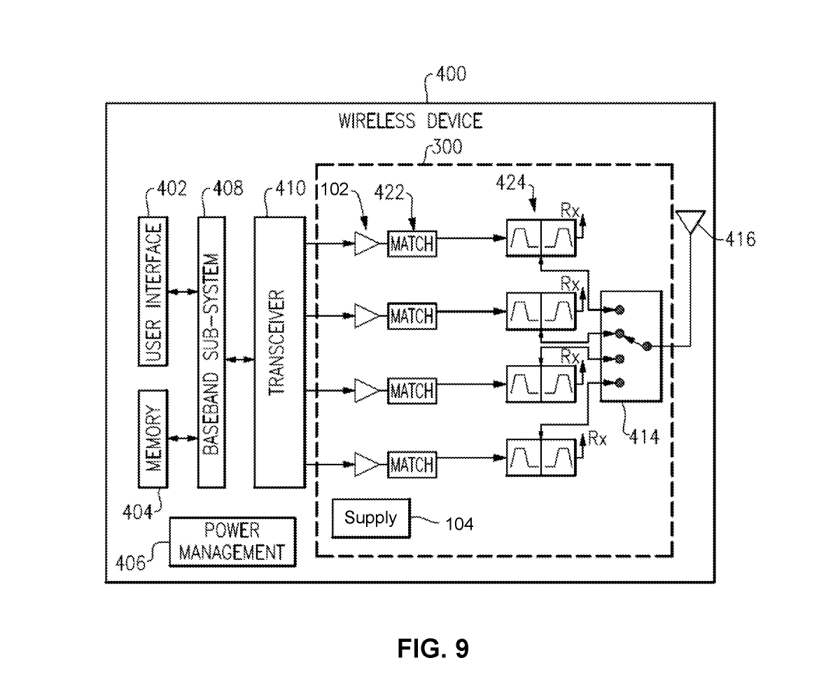

FIG. 9 depicts an example wireless device 400 having one or more advantageous features described herein. In the context of a module having one or more features as described herein, such a module can be generally depicted by a dashed box 300, and can be implemented as, for example, a front-end module (FEM).

Referring to FIG. 9, power amplifiers (PAs) 102 can receive their respective RF signals from a transceiver 410 that can be configured and operated to generate RF signals to be amplified and transmitted, and to process received signals. The transceiver 410 is shown to interact with a baseband sub-system 408 that is configured to provide conversion between data and/or voice signals suitable for a user and RF signals suitable for the transceiver 410. The transceiver 410 can also be in communication with a power management component 406 that is configured to manage power for the operation of the wireless device 400. Such power management can also control operations of the baseband sub-system 408 and the module 300.

The baseband sub-system 408 is shown to be connected to a user interface 402 to facilitate various input and output of voice and/or data provided to and received from the user. The baseband sub-system 408 can also be connected to a memory 404 that is configured to store data and/or instructions to facilitate the operation of the wireless device, and/or to provide storage of information for the user.

In the example wireless device 400, outputs of the PAs 102 are shown to be matched (via respective match circuits 422) and routed to their respective duplexers 424. Such amplified and filtered signals can be routed to an antenna 416 through an antenna switch 414 for transmission. In some embodiments, the duplexers 424 can allow transmit and receive operations to be performed simultaneously using a common antenna (e.g., 416). In FIG. 9, received signals are shown to be routed through the duplexers 424 to “Rx” paths that can include, for example, one or more low-noise amplifiers (LNAs).

In the example of FIG. 9, supply for the PAs 102 can be provided by a supply circuit 102. Such a supply circuit can provide a combination of regulated and unregulated supply voltages to different stages of a power amplifier, as described herein.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. An amplification system comprising:
an amplifier circuit including a plurality of stages and configured to amplify a signal; and
a supply circuit configured to provide a regulated supply voltage to at least one stage of the plurality of stages, and an unregulated supply voltage to at least one stage of the plurality of stages.

2. The amplification system of claim 1 wherein the supply circuit includes a regulator configured to provide the regulated voltage.

3. The amplification system of claim 2 wherein the regulator includes a low-dropout regulator.

4. The amplification system of claim 1 wherein the at least one stage being provided with the unregulated voltage includes a final one of the plurality of stages.

5. The amplification system of claim 4 wherein the supply circuit is configured to provide the unregulated voltage to only the final stage, and the regulated voltage to the other stage(s).

6. The amplification system of claim 1 wherein the unregulated voltage is based on a battery voltage.

7. The amplification system of claim 6 wherein the unregulated voltage is substantially same as the battery voltage.

8. The amplification system of claim 1 wherein the amplifier circuit is configured as a power amplifier circuit.

9. The amplification system of claim 9 wherein the signal amplified by the power amplifier circuit is configured for transmission.

10. The amplification system of claim 1 wherein the amplification system is configured as at least a part of a front-end system.

11. The amplification system of claim 1 wherein the amplification system is configured to support a wireless operation.

12. (canceled)

13. A radio-frequency module comprising:
a packaging substrate configured to support a plurality of components; and
an amplification system implemented on the packaging substrate, and including an amplifier circuit having a plurality of stages and configured to amplify a signal, the amplification system further including a supply circuit configured to provide a regulated supply voltage to at least one stage of the plurality of stages, and an unregulated supply voltage to at least one stage of the plurality of stages.

14. The radio-frequency module of claim 13 wherein the amplifier circuit is implemented on a semiconductor die which is then mounted on the packaging substrate.

15. The radio-frequency module of claim 14 wherein the supply circuit is also implemented on the semiconductor die.

16. The radio-frequency module of claim 14 wherein the supply circuit is implemented on another semiconductor die.

17. The radio-frequency module of claim 13 wherein the amplifier circuit is configured as a power amplifier circuit.

18. The radio-frequency module of claim 17 wherein the radio-frequency module is configured as a front-end module.

19. The radio-frequency module of claim 18 further comprising an antenna switch circuit configured to route the amplified signal from the power amplifier circuit to an antenna for transmission.

20. A wireless device comprising:
a transceiver configured to process a signal;
a front-end module in communication with the transceiver and including an amplifier circuit having a plurality of stages and configured to amplify the signal, the front-end module further including a supply circuit configured to provide a regulated supply voltage to at least one stage of the plurality of stages, and an unregulated supply voltage to at least one stage of the plurality of stages; and
an antenna in communication with the front-end module and configured to support an operation associated with the signal.

21. The wireless device of claim 20 wherein the amplifier circuit is configured as a power amplifier circuit, and the signal is configured to be transmitted through the antenna.
